(19) United States
(12) Patent Application Publication
(10) Pub. No.: US 2005/0118533 A1
(43) Pub. Date: Jun. 2, 2005

(54) Planarization of substrate pits and scratches

(76) Inventors: Paul B. Mirkarimi, Sunol, CA (US); Sherry L. Baker, Pleasanton, CA (US); Daniel G. Stearns, Los Alto Hills, CA (US); Eberhard A. Spiller, Livermore, CA (US)

Correspondence Address: Deputy Laboratory Counsel For Intellectual;Property, Lawrence Livermore National Laboratory, P.O. Box 808, L-703, Livermore, CA, 94551-0808, US

(21) Appl. No.: 10/964,048

(22) Filed: Oct. 12, 2004

Related U.S. Application Data
(63) Continuation-in-part of application No. 10/086,614, filed on Mar. 1, 2002.

(51) Int. Cl. G03F 7/36

(52) U.S. Cl. 430/316; 430/5; 430/313

(57) ABSTRACT

Ion-beam based deposition technique are provided for the planarization of pit and scratch defects in conjunction with particle defects. One application of this planarization technique is to mitigate the effects of pits and scratches and particles on reticles for extreme ultraviolet (EUV) lithography. In the planarization process, thin Si layers are successively deposited and etched away where the etching is directed at angles well away from normal incidence to the substrate to planarize pits and scratches without causing the particle defects to get too large; this is followed by a normal incidence etching process sequence designed primarily to planarize the particles but which will also planarize the pits and scratches to completion. The process also shows significant promise for planarizing substrate roughness.

This application is a continuation-in-part of U.S. patent application Ser. No. 10/086,614, titled: “Ion-Assisted Deposition Techniques For The Planarization Of Topological Defects,” Filed Mar. 1, 2002, incorporated herein by reference.

The United States Government has rights in this invention pursuant to Contract No. W-7405-ENG48 between the United States Department of Energy and the University of California for the operation of Lawrence Livermore National Laboratory.

### BACKGROUND OF THE INVENTION

1. Field of the Invention

The present invention relates to the reduction of defects of extreme ultraviolet lithography mirrors, and more specifically, it relates to planarizing pits and scratches in the substrates of such mirrors and the ability to do so while simultaneously planarizing substrate particles.

2. Description of Related Art

Reticle blanks for extreme ultraviolet lithography are fabricated by depositing reflective multilayer coatings such as Mo/Si on superpolished substrates. These reflective reticles are a significant departure from conventional transmission reticles, and the reflective reticles must be nearly defect-free in the sense that there cannot be localized structural imperfections in the coating that perturb the reflected radiation field sufficiently to print at the wafer. Simulations indicate that substrate pits only several tens of nm in depth and width could perturb the reflective multilayer enough to print in commercial extreme ultraviolet lithography tools. Consequently it is very important to develop methods to minimize the effect of small substrate pits and scratches on the reflective multilayer film, particularly since no repair technique has been envisioned for this class of multilayer defects.

One promising approach to eliminating such defects is to develop a coating process that sufficiently planarizes away the substrate asperities so that the defects do not print. Mirkarimi et al. have previously shown, in U.S. patent application Ser. No. 10/086,614, incorporated herein by reference, that by integrating into the film deposition process the direct etching of the mask substrate at normal incidence, the growth of defects nucleated by particles can be suppressed. The efficacy of this approach is likely due to the strong dependence of the etch rate on the local angle of incidence. As shown in FIG. 1, the etch rate has a peak around an angle of 45-50 degrees from the normal. Consequently when etching a defect nucleated by a particle, the sides of the defect etch faster than the top. FIGS. 2A-2C shows schematically how the defect profile evolves. The enhanced etching at the sides can cause the profile to narrow until the sides meet and the defect essentially collapses.

Unfortunately, etching at normal incidence is not very effective for the planarization of concave substrate defects such as pits and scratches. The problem is illustrated in FIGS. 3A-3C. In this case, the enhanced etch rate at the sides of the pit or scratch causes the profile to broaden, which essentially increases the size of the defect

A technique is therefore needed for planarization of substrate pits and scratches in addition to particles.

### SUMMARY OF THE INVENTION

It is an object of the present invention to provide techniques for planarizing pits and scratches in extreme ultraviolet lithography mirror substrates.

This and other objects will be apparent to those skilled in the art based on the disclosure herein.

The invention is an ion-assisted deposition technique for the planarization of pit and scratch defects. One application of this planarization technique is to mitigate the effects of pits and scratches on reticles for extreme ultraviolet (EUV) lithography. Reticles for EUV lithography are fabricated by depositing high EUV reflectance Mo/Si multilayer films on superpolished substrates and pit and scratch defects in the substrate can result in unacceptable (“critical”) defects in the reflective Mo/Si multilayer coatings. There is also currently no technique envisioned to repair multilayer phase defects originating from substrate pits and scratches. The technique described by Mirkarimi et al. in U.S. patent application Ser. No. 10/086,614, in which Si layers were successively deposited and etched away at near-normal incidence, works well in planarizing substrate particles but does a mediocre job of planarizing substrate pits and scratches. A key element of this new invention is to conduct the etching at angles well away from normal incidence to the substrate, which enhance pit and scratch planarization. Substrate test samples with 70 nm diameter and 70 nm wide pits were planarized using etch angles of 40-69 degrees to produce topological defects with depths of ˜1 nm, rendering them harmless to the lithographic process. The 45 degree etch process was followed by normal incidence etch processes similar to that described by Mirkarimi et al. in U.S. patent application Ser. No. 10/086,614 to enable pits and particles to be planarized simultaneously. The process shows significant promise for mitigating substrate scratches as well.

This invention has the potential to impact the performance of extreme ultraviolet lithography, an area that has been under investigation at Lawrence-Livermore National Laboratory (LLNL) for many years. There is a strong commercial driving force for increased miniaturization in electronic devices, and hence, extreme ultraviolet lithography has significant commercial potential. A critical element of this technology is the reticle, and this invention addresses a very challenging problem in the development of the commercially viable reticle.

### BRIEF DESCRIPTION OF THE DRAWINGS

The accompanying drawings, which are incorporated into and form part of this disclosure, illustrate embodiments of the invention and together with the description, serve to explain the principles of the invention.

FIG. 1 is a plot of the Si etch rate, normalized to the normal incidence etch rate, as a function of incident angle for two conditions of the Ar ion beam.

FIGS. 2A-2C illustrate the progressive effect of normal incidence etching on a defect nucleated by a particle.

FIGS. 3A-3C illustrate the progressive effect of normal incidence etching on a defect nucleated by a pit or scratch.

FIGS. 4A-4C illustrate the progressive effect of etching at grazing incidence on a defect nucleated by a pit or scratch.

FIG. 5 plots Power Spectral Density (PSD) of the sample surface (I) after fabrication by electron beam lithography, (II) after removal of the pits by silicon deposition and etching, and (II) after ion polishing and multilayer deposition.

FIG. 6 is a plot of measured reflectivity versus wavelength of a Mo/Si multilayer on a substrate that originally had 70 nm pits and had a roughness of 0.68 nm.

FIG. 7 is a cross-sectional TEM image of coating V1683/1686/1687 deposited on a nominally 70×70 nm scratch.

FIG. 8 shows a cross-sectional transmission electron microscopy image of 70 nm particle planarization for the V1799-V1831 process sequence.

FIG. 9 shows a cross-sectional transmission electron microscopy image of 70 nm pit planarization for the V1799-V1831 process sequence.

FIG. 10A shows the surface of a glass substrate as measured by atomic force microscopy before planarization.

FIG. 10B shows the surface of a glass substrate as measured by atomic force microscopy and after planarization

FIG. 10C shows the power spectral density (PSD) for the surfaces shown in FIGS. 10A and 10B.

FIGS. 11A-C provide data showing the roughening of a Si film that occurs when a large amount of material is removed in one step.

FIG. 12 shows the PSDs of three samples.

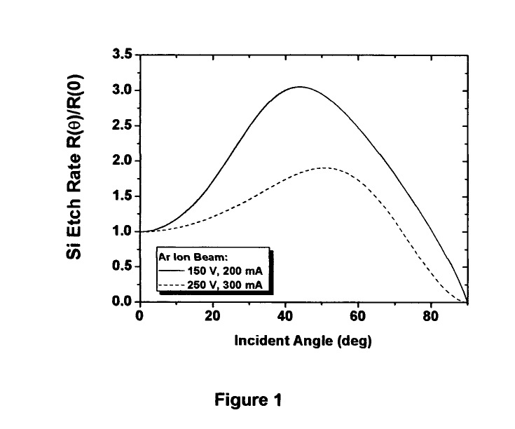

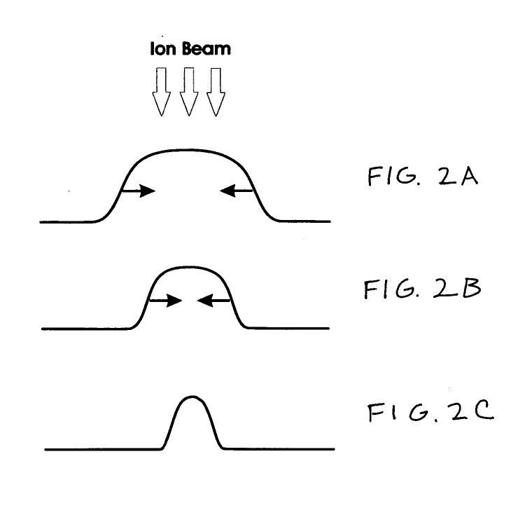

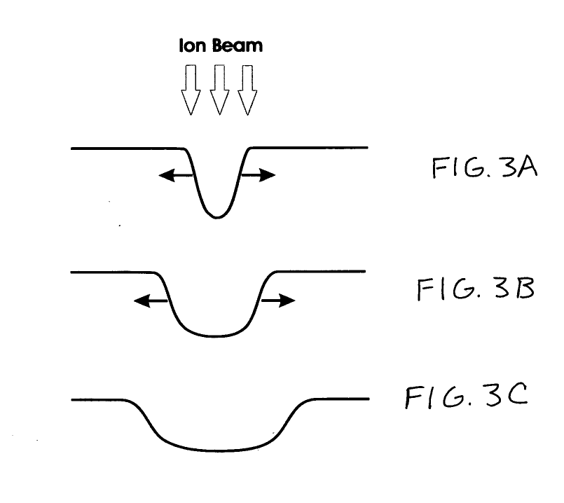

### DETAILED DESCRIPTION OF THE INVENTION

Planarization of Pits

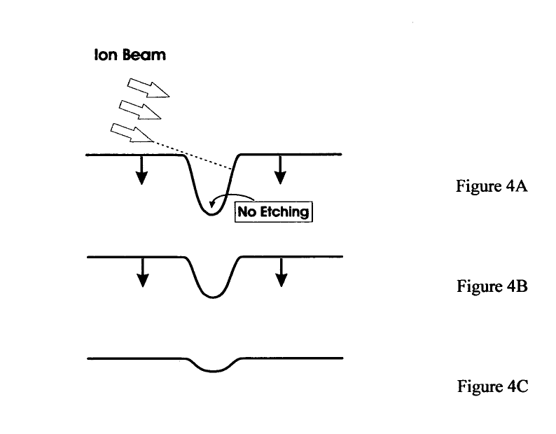

An embodiment of the invention includes a method for planarizing pits and scratches on substrates, especially on EUVL mask substrates. Another embodiment further includes planarizing particles on a substrate. The process includes depositing a film on a substrate and etching the film at an angle of incidence away from normal incidence. In practice it is useful to repeat the deposition and etch steps in a periodic sequence to enhance the planarization process and suppress surface roughening. The key planarization mechanism in this process is shadowing, as illustrated in FIG. 4. Due to shadowing, the etch rate at the bottom of the pit or scratch is essentially zero. The large difference between the etch rates at the surface of the film and the bottom of the defect causes the depth of the defect to rapidly decrease.

In order to test the pit planarization process, substrates with suitable pit defects were obtained. Samples with 70 nm deep and wide pits were fabricated by a standard electron beam lithography process. Due to the fabrication process, the surface of this substrate had a roughness of 0.68 nm. It is not possible to obtain good reflectivity with a standard multilayer coating on such a rough substrate. The following steps were used to planarize the substrate pits, reduce the roughness to an acceptable level and produce a high reflectivity coating.

A layer of Si of 8.7 nm thickness was deposited with an ion beam sputter deposition system using Ar ions and a beam voltage of ˜600 Volts. The deposition was at normal incidence. Subsequently, 7.6 nm of the Si was removed by bombarding the film with another ion gun. The ion energy was 250 eV and the incidence angle of the ions was 69° from normal. Based on simulations, the planarization process for pits was expected to be very effective if the incidence angle of the ions would be kept between approximately 45 to 70 degrees from the substrate normal. Data shows that excellent planarization of the pits can be achieved over the range of etch energies that we sampled (150-550 eV). This suggests that the process is not very sensitive to the etch energy and pit planarization may be achievable with energies less than 150 eV and greater than 550 eV.

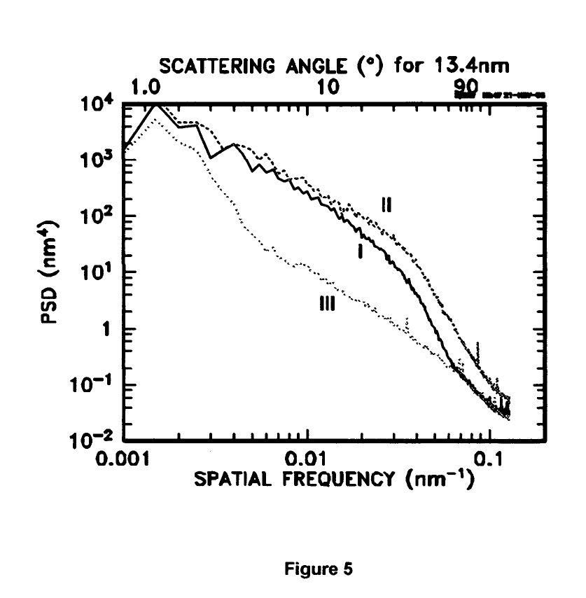

This process was repeated for 25 cycles. Inspection of the sample by atomic force microscopy showed that the pits had been smoothed below the detectability threshold, which is estimated to be ˜1 nm due primarily to the rough ness of the surface. The roughness after this process step was 0.88 nm rms (from the original ˜0.68 nm rms). FIG. 5 shows the measured Power Spectral Density (PSD) of the surface before and after this step as curves I and II.

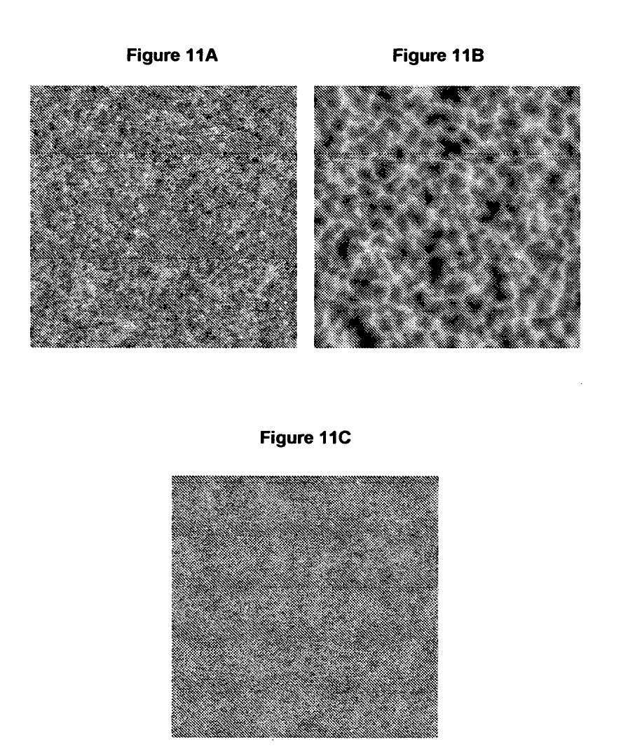

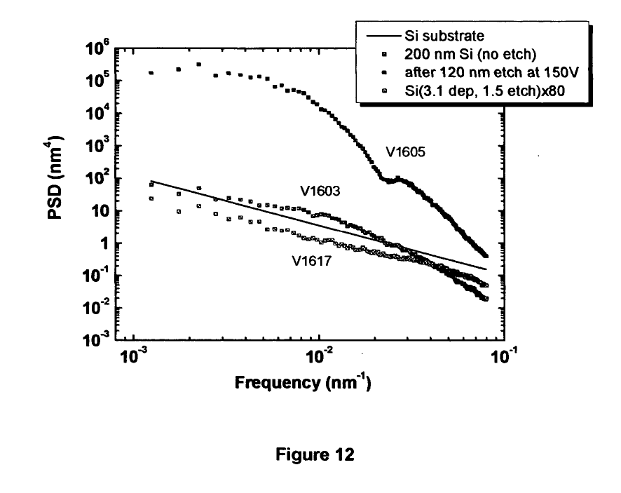

The present technique relies on depositing very thin Si layers and etching most of them away in a sequential (coat and etch) process. The uniqueness of this process is given extra support by the information in FIGS. 11A-C, and FIG. 12, discussed below in the section on planarizing substrate roughness.

To reduce surface roughness, a process similar to the pit removal process described above was used; however, the ion beam for polishing was incident at normal incidence. Si of 4.9 nm was deposited using 600 V ions hitting the target at 45° with the flux from the target at normal incidence to the substrate. A 3.8 nm thick layer of the Si was removed by bombarding the substrate near normal incidence with Ar ions at 150 eV. This process was repeated 50 times.

A multilayer was deposited of 50 periods with 4.2 nm Si and 2.7 nm Mo in each period. Ion energy was 600 V and the deposition was at normal incidence. Curve III of FIG. 5 shows the PSD of the top of this coating. Roughness has been reduced to 0.29 nm.

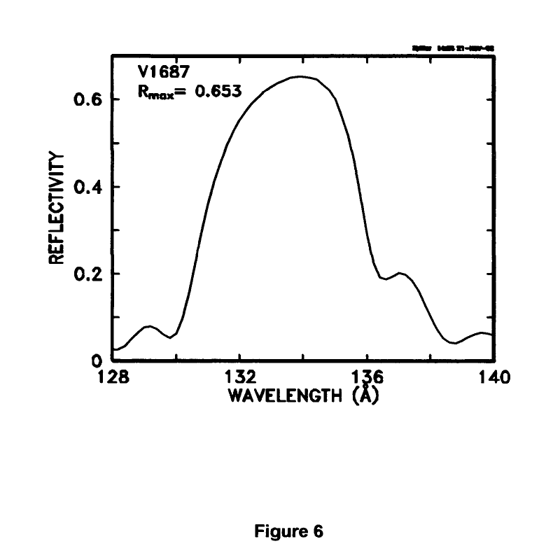

The measured reflectivity of the coating is plotted in FIG. 6. The peak reflectivity of 65.3% is only slightly lower than the peak reflectivity of 67.6% obtained from a sample produced in the same deposition run on a smooth Si substrate.

Planarization of Substrate Scratches

In addition to substrate pits, this technique is effective in reducing the size of small substrate scratches. This is particularly valuable when the substrate manufacturers leave small, residual scratches on the surface of the substrates after polishing. Substrate scratches are more challenging to smooth than the pits because of their one-dimensional topology, which effectively limits the mass transport and surface relaxation to one spatial direction. In the demonstration described above for pit planarization, the substrate with pit defects was made to also contain trenches that simulated scratch-like defects, and these were also characterized by cross-sectional (X) images (of the defects) obtained using transmission electron microscopy (TEM) as well as AFM. The XTEM images provide a view of the evolution of the defect as it is coated, and give more accurate structural information in the early stages of planarization when the defects have a high-aspect ratio.

Accurel Systems in Sunnyvale has a dual beam FIB/SEM (a TEM). A dual beam was desired since it was anticipated that finding the smoothed defects could be challenging and the second beam through the SEM component provides added resolution. A sample was prepared and viewed at Accurel Systems. It was the smoothed pit sample discussed above, also referred to herein as coating V1683/1686/1687. A synthesized scratch (trench) in the sample was characterized; one advantage of viewing a scratch is that, unlike a pit, the XTEM images should not have perturbed and unperturbed multilayer superimposed upon the same image (i.e., the contours of the layering should be more clearly delineated).

Fiducial marks are located with the SEM and a thin (˜70 nm) slice is milled out of the sample at the position of the defect A sacrificial layer of Pt is deposited on the sample surface before milling in order to prevent staining of the sample by the Ga ion beam. The small slice is then removed and transferred to the TEM for viewing.

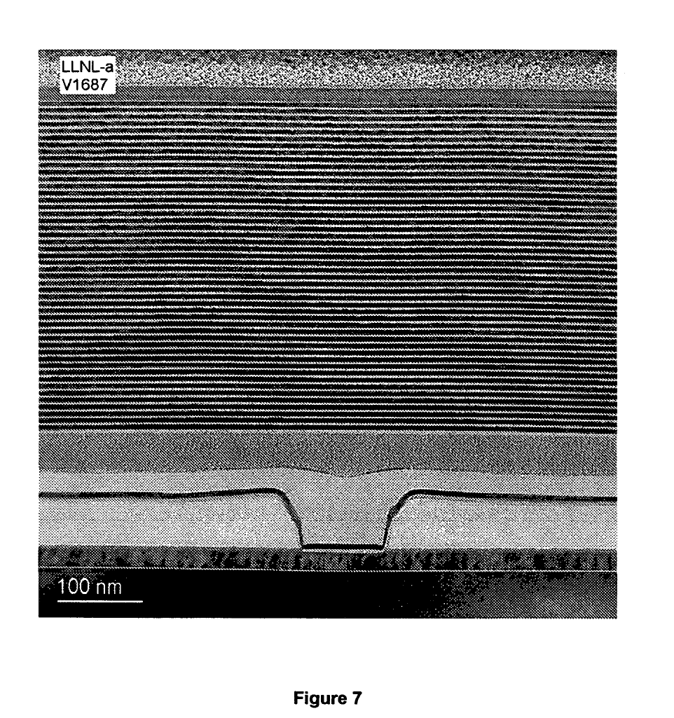

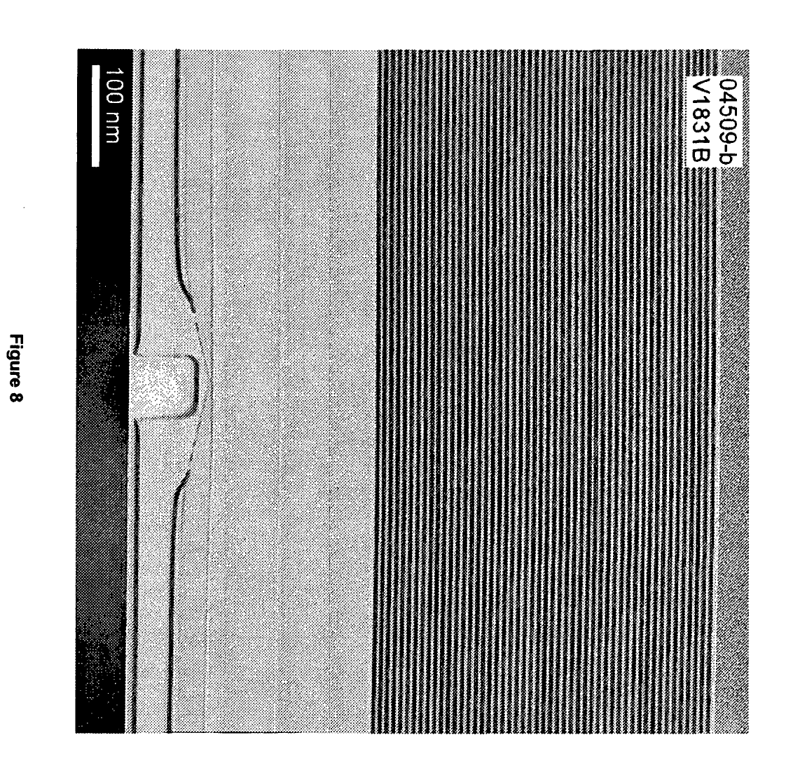

FIG. 7 shows the XTEM image of coating V1683/1686/1687 on a scratch having nominal dimensions of 70×70 nm. For the first coating run (V1683), the substrate was initially coated with a thin Si/Mo/Si buffer layer, which can be seen as the black line along the surface of the scratch. This was to provide contrast for XRD and XTEM measurements. The first coating run (V1683) also included 25 cycles of Si deposited at normal incidence and etched at 69° using a 250 eV ion beam. This part of the process was intended to smooth the scratch and the residual Si is seen as the light material that fills up the scratch. The second coating run (V1686) consisted of 50 cycles of Si deposited and etched at normal incidence using a 150 eV ion beam. The residual Si from this coating is seen as the grainy, gray layer in the image. The main purpose of this coating was to remove the high frequency roughness produced by 69° off normal etching (V1683), although it is apparent that this coating also completed the planarization of the scratch. The roughness was reduced from 0.88 nm to 0.29 nm after V1686 was applied. The final coating run (V1687) was a high reflectance Mo/Si multilayer consisting of 50 periods of 6.8 nm, and is seen as the alternating bands in the image. The measured EUV reflectivity of this multilayer was 65.3%. It is apparent that ion beam milling damaged the top three or four periods, in spite of the protective Pt layer.

The substrate pits in V1683/V1686/V1687 were completely smoothed away as far as one could determine based on the noise due to the roughness. The substrate scratches, which were used in the XTEM image in FIG. 7, were smoothed to a final depth of ˜2.5 nm (after the V1687 multilayer coat) according to AFM.

Planarization of Pits/Scratches and Particles Simultaneously

A key component of the technique described above is to use an incidence etch angle that is significantly off-normal (e.g., about 69 degrees from normal). While excellent pit/scratch planarization occurred under these conditions, there were two drawbacks. The first, which is by far the most important drawback, is that substrate particles are not planarized (they actually nucleate larger defects under these conditions) and second is that the roughness of the surface was increased, requiring an additional step designed to planarize away the roughness, as discussed above. Thus, an improved process, which does not have those drawbacks, is provided below.

All of the experimental deposition runs used in the discussion of this improved process used an etch energy of 250 eV and an etch current of 300 mA. The particles were ˜70 nm×70 nm to start and the pits were ˜−70 nm×70+ nm to start The particle and pit samples were processed simultaneously (i.e., the process steps were performed on both at the same time). About ˜8.7 nm of Si was deposited for each cycle prior to etching for all of the process steps.

A key component of the improved process was the fact that the design of the first process step should emphasize pit planarization without causing any particles to get too large. An etch angle is used that is closer to normal incidence than the 69 degree etch angle used in the pit planarization process embodiment described above. In the demonstration, described below, for the improved process, 45 degrees was used instead of 69 degrees for the etch angle (the angle of incidence of the Ar ion beam used for etching relative to the substrate normal). This has an added (minor) benefit that the roughness is not increased as much at this etch angle closer to normal incidence. About 8.7 nm of Si was deposited and about 7.4 nm was etched away. This sequence was repeated 15 times. We note that since this demonstration run was performed we have also obtained excellent pit planarization for an etch angle of 40 degrees from normal and we expect that one could be able to go several degrees lower in etch angle and still achieve excellent pit planarization with the proper optimization of the amount etched per cycle at those angles.

The second and subsequent planarization process steps were designed to emphasize particle planarization but to also have a beneficial effect on pit and scratch planarization. In the demonstration, an etch angle of 0 degrees was used (normal incidence). For most of this part, about 8.7 nm of Si was deposited and about 7.4 nm was etched away. However, for a small fraction of the cycles, about 1.2 nm more was etched away than was deposited per cycle, which was found to enhance the planarization. To do this for more than several cycles can results in turning the particle into a significant crater in the substrate, which can be undesirable.

Runs Demonstrating Improved Embodiment Described Above

Run V1799. 15 cycles etching at 45 degree angle. 7.4 nm etched per cycle. This step is designed primarily to smooth the pits without causing the particles to get too large.

AFM Results of Run V1799: (i) Pit Depth=−12.2 nm, FWHM=51 nm; (ii) Particle: Height=62.8 nm, FWHM=152 nm.

Run V1800 (using V1799 samples as substrates). 20 cycles etching at 0 degrees etch angle. 7.2 nm etched per cycle. This step is designed primarily to focus on particles (but also to smooth pits).

AFM Results of Run V1800: (i) Pit Depth=−2.1 nm, FWHM=155 nm; (ii) Particle: Height=5.9 nm, FWHM=193 nm.

Run V1801 (using V1800 samples as substrates). Like V1800 above except 9.9 nm etched per cycle (i.e., some over-etching). Only 5 cycles of etching.

AFM Results of Run V1801: (i) Pit Depth=Undetectable depth (above background roughness), thus, effectively smoothed away. On a close-up AFM scan, estimate<1 nm; (ii) Particle: Height=Unusual shape and hard to quantify at this stage.

Run V1808 (using V1801 samples as substrates). Similar to V1800 above. 40 more cycles of etching.

AFM Results of Run V1808: (i) Pit Depth=−0.3 nm; FWHM indeterminate; (ii) Particle: Height=1.4 nm, FWHM=376 nm.

Run V1816 (using V1808 samples as substrates). Similar to V1800 above. 60 more cycles of etching.

AFM Results of Run V1816: (i) Pit Depth=−0.3 nm; FWHM=indeterminite; (ii) Particle: Height=1.03 nm, FWHM=387 nm.

Table 1, shown below, is the V1799/V1800/V1801/V1808/V1816 process sequence. In each cycle ˜8.7 nm of Si was deposited before being etched by the amount denoted in the Table.

TABLE 1

| | | Amount of | | | | | |
|---|---|---|---|---|---|---|---|
| | | Si etched | Pit | Pit | Particle | Particle | Etch |
| Sample | # of | per cycle | depth | FWHM | depth | FWHM | angle |
| # | cycles | (nm) | (nm) | (nm) | (nm) | (nm) | (deg) |
| V1799 | 15 | 7.4 | −12.1 | 51.1 | 62.8 | 151.7 | 45 |
| V1800 | 20 | 7.2 | −2.1 | 155.3 | 5.86 | 193.4 | 0 |
| V1801 | 5 | 9.9 | −<1 | — | — | — | 0 |
| V1808 | 40 | 7.4 | −0.3 | — | 1.39 | 376.3 | 0 |
| V1816 | 60 | 7.2 | −0.3 | ″ | 1.03 | 387.2 | 0 |

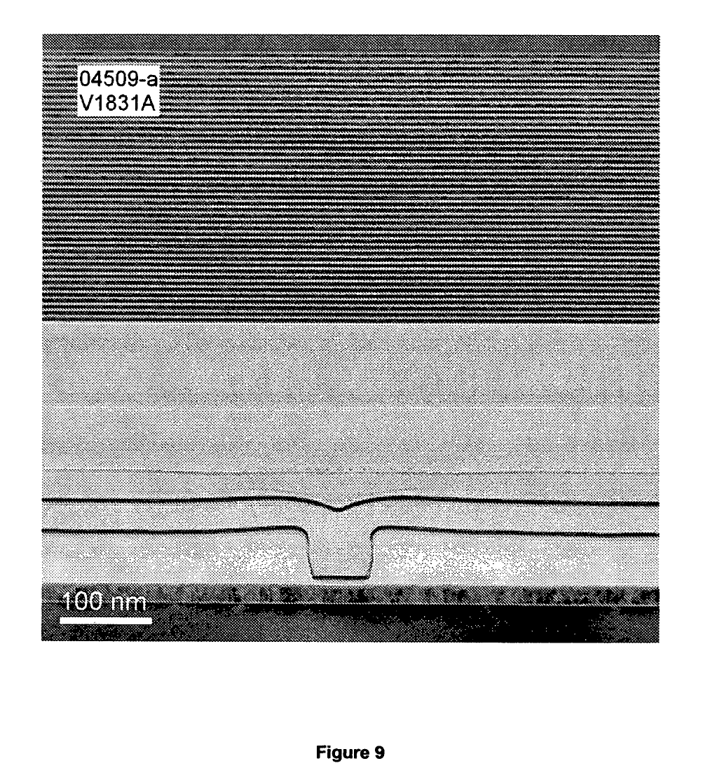

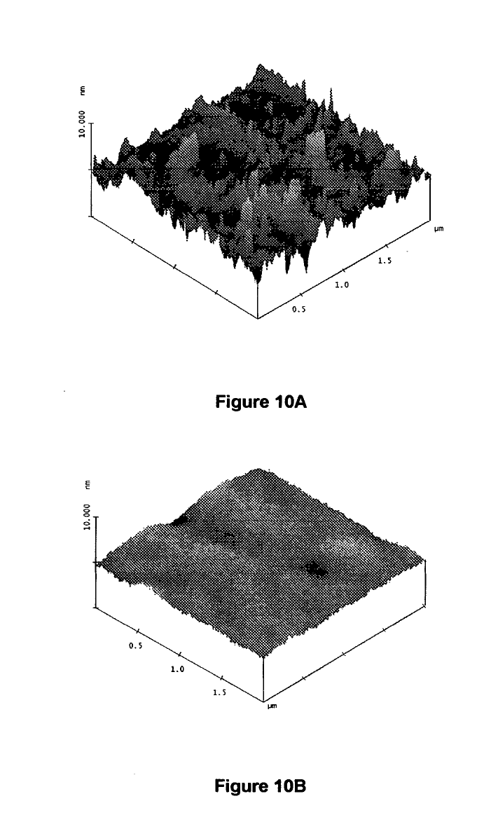

The particle and pit samples used in the V1799-V1816 process sequence had a standard Mo/Si reflective multilayer film deposited on them in deposition run V1831. Cross-sectional transmission electron microscopy was performed on the samples and the images are shown in FIGS. 8 and 9 below for smoothed particles and pits respectively. These images convincingly demonstrate the effectiveness of the planarization process.

Planarizing Substrate Roughness

The reflectivity of EUV multilayer films is highly dependent on the high spatial frequency roughness of the underlying substrate. For a EUVL lithography tool, the throughput (i.e., how many wafers one can process with integrated circuits per hour) is very dependent on the reflectivity of the reflective optics and mask in the tool (although the optics have more importance since they represent several reflections versus one for the lone mask). One can planarize roughness by etching the Si layers in a Mo/Si multilayer film or by etching the Si layers in a pure Si planarization layer and then depositing the (unetched) Mo/Si multilayer on top of the planarization layer. One disadvantage of the former process is that with heavy etching one can entrap a significant amount of inert gas (such as Ar) into the film from the ion source, and this will reduce the EUV reflectivity of the multilayer film. One may also increase the roughness of the Mo—Si interfaces with heavy etching. By employing the present technique, one can coat and etch (and etch significantly) to planarize substrates with large roughness values and the multilayer needs to only be deposited after this process is completed, so there is no resulting damage to the multilayer.

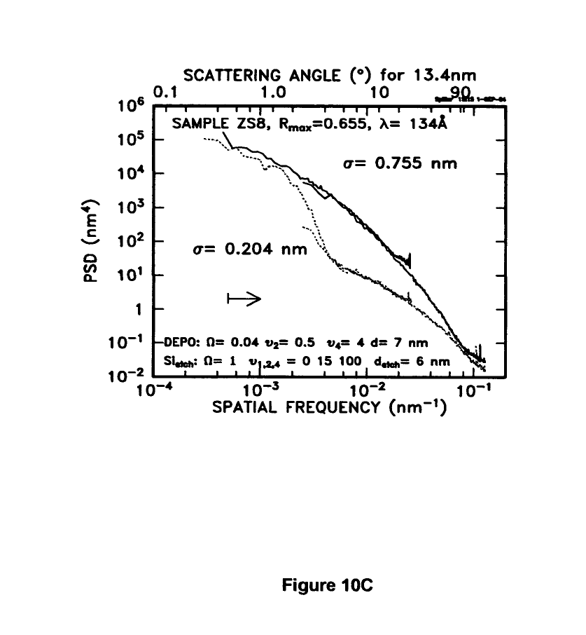

The present method has been used to smooth a substrate having an initial roughness of 0.75 nm rms to a roughness of 0.20 nm rms. This process makes such a substrate smooth enough to use it for mirrors in a EUV stepper without the need for super-polish. FIGS. 10A and 10B show the surface of the substrate before and after applying the present coat-and-etch planarization process. FIG. 10C shows the power spectral density before (black) and after planarization (red, dashed). The measured EUV reflectivity after a standard Mo/Si multilayer film was deposited on the planarized substrate was 65.5%; to the best of our knowledge this is a record EUV reflectivity for deposition on such a rough (0.75 nm rms) substrate.

FIGS. 11A-C show that if one simply deposits a thick Si layer and etches it back, the surface looks much worse (i.e., the surface has higher “low spatial frequency roughness” which cannot be smoothed). FIGS. 11A-C provide data showing the roughening of a Si film that occurs when a large amount of material is removed in one step −120 nm in this case. FIG. 11A is the surface of a 200 nm thick Si film. FIG. 11B shows the surface after 120 nm of Si is etched at 150 V. FIG. 11C shows the surface when the deposition and etch steps are subdivided into 80 cycles. Note that the total amount of removed Si shown FIG. 11B is the same as that shown removed in FIG. 11C. The AFM data for a 2000 nm scan, and a 512×512 image for FIGS. 11A-C were as follows: FIG. 11A: V1603—200 nm Si, no etch, rms=0.11 nm; FIG. 11B: V1605—200 nm Si dep+120 nm etch at 150 V, rms=5.0 nm; FIG. 11C: V1617—Si (3.1 nm dep, 1.5 nm etch)×80, rms=0.075 nm.

The PSDs of the three samples are shown in FIG. 12. It is interesting to note that the roughening due to the long etch step occurs at all spatial frequencies, but there is relatively more roughening produced at the lower frequencies. This is problematic because it is very difficult to smooth lower frequency roughness away. There are many experimental and theoretical studies of this behavior in the literature. Hence it is much better to work with a large number of small etch steps and thereby avoid the roughening.

The foregoing description of the invention has been presented for purposes of illustration and description and is not intended to be exhaustive or to limit the invention to the precise form disclosed. Many modifications and variations are possible in light of the above teaching. The embodiments disclosed were meant only to explain the principles of the invention and its practical application to thereby enable others skilled in the art to best use the invention in various embodiments and with various modifications suited to the particular use contemplated. The scope of the invention is to be defined by the following claims.

1. A method for planarizing a substrate pit or scratch, comprising:
depositing a film onto a substrate; and
etching at an angle away from normal incidence to said substrate at least a portion of said film off of said substrate.

2. The method of claim 1, including a method for planarizing a substrate particle, comprising:
depositing a second film onto said substrate; and
etching at an angle near normal incidence at least a portion of said second film off of said substrate

3. The method of claim 1, wherein the steps of depositing a film and etching at an angle are repeated.

4. The method of claim 1, wherein the steps of depositing a film and etching at an angle are repeated for about 25 cycles.

5. The method of claim 2, wherein the steps of depositing a second film and etching are repeated.

6. The method of claim 1, wherein the step of etching at an angle away from normal incidence is provided by an etching source producing an etching beam directed at said substrate at said angle.

7. The method of claim 6, wherein said etching beam comprises an ion beam.

8. The method of claim 7, wherein said ion beam comprises an Ar ion beam.

9. The method of claim 6, wherein said etching source comprises an ion gun.

10. The method of claim 9, wherein said ion gun comprises an argon ion gun.

11. The method of claim 7, wherein said ion beam comprises energy within a range from about 150 eV to about 550 eV.

12. The method of claim 7, wherein said ion beam comprises energy of about 250 eV.

13. The method of claim 1, wherein said angle comprises a grazing angle with respect to said substrate.

14. The method of claim 1, wherein said angle is within a range from about 40° to about 70° from normal to said substrate.

15. The method of claim 1, wherein said angle is about 69° from normal to said substrate.

16. The method of claim 1, wherein said film comprises Si.

17. The method of claim 1, wherein the step of depositing a film is carried out with an ion beam sputter deposition system.

18. The method of claim 1, wherein the step of depositing a film is carried out with an argon ion beam sputter deposition system.

19. The method of claim 1, wherein said substrate is for use in a reticle for extreme ultraviolet lithography.

20. The method of claim 1, further comprising depositing a multilayer film onto said substrate.
